(19) United States
(12) Patent Application Publication
(10) Pub. No.: US 2006/0151207 A1
(43) Pub. Date: Jul. 13, 2006

(54) RF shielding structure

(76) Inventors: Brian Redman, Richmond (CA); Yat Shun Yu, Burnaby (CA)

Correspondence Address: Michael D. Bednarek;SHAW PITTMAN LLP, 1650 Tysons Boulevard, McLean, VA, 22102, US

(21) Appl. No.: 11/001,339

(22) Filed: Dec. 2, 2004

(51) Int. Cl. H05K 9/00; H01R 4/00

(52) U.S. Cl. 174/355; 174/377; 174/387; 174/369

(57) ABSTRACT

An RF shielding liner. The RF shielding liner is configured to be installed or sandwiched between a lid and a frame of an electronic apparatus. The frame includes at least two compartments separated by partition walls. The RF shielding liner is made of conductive materials and includes a plurality of protrusions on at least one side. When the lid covers the frames to form an enclosure, the plurality of protrusions of the RF shielding liner are deformed against the tops of the partition walls, thereby forming a Faraday Cage necessary for preventing the escape of unwanted radio emissions.

### BACKGROUND

1. Field of the Invention

The present invention relates generally to an RF (Radio Frequency) shielding structure and more particularly, to an enclosure structure that can effectively prevent RF from emitting outside of the enclosure.

2. Background of the Invention

In a typical radio design for wireless communications, it may be necessary to isolate the different internal sections of the radio from one another to prevent them from adversely affecting each other through uncontrolled emissions of radio (RF) and electromagnetic (EMC) energy. A typical shield construction 10, as shown in FIG. 1, includes a series of perimeter walls 13 in shield frame 11 enclosing various radio stages 14, with one lid 12 covering the whole assembly. Lid 12 is removable for inspection and servicing. Conventional inter-stage RF shielding 10 relies on flexible fingers 15 that are cut into shield lid 12 and are bent down to make contact along the top of perimeter walls 11 to complete a Faraday Cage, which is a structure that isolates an electronic system from outside interference.

A deficiency with this technique, however, is that the cuts used to make fingers 15 form slot antennas, which at higher frequencies, can cause spurious harmonic emissions through lid 12 and into the outside world, resulting in failure to comply with certain FCC regulations pertaining to communications equipment.

To solve the problem, one solution is to utilize a cast-metal lid with a formed set of fingers attached inside. In such configuration, these fingers contact with the tops of partition walls. This solution is effective from an RF standpoint, but is costly, heavy and bulky. A second solution is to use a conductive-coated plastic shield, where the walls and lid are molded as one piece, and the electrical contact between the shield and the printed circuit board is established by a conductive, flexible gasket material attached to the bottom edges of the partition walls. This solution is relatively costly, and requires a lot of PCB area. Furthermore, this solution is less effective at higher frequencies. A third solution is to directly solder a waffle-iron-style formed metal can to the PCB. This solution is relatively inexpensive, and quite effective, but can not be opened for service or inspection without risking damage to the radio.

Accordingly, an RF shielding construction that effectively prevents RF emission is desirable.

### BRIEF SUMMARY OF THE INVENTION

An RF shielding structure in accordance with a first embodiment of the present invention includes a frame including two or more compartments separated by partition walls, a lid configured to mate with the frame, and an RF shielding liner having a plurality of protrusions made of a conductive material. When the RF shielding liner is sandwiched between the frame and the lid, some or all of the plurality of protrusions are deformed between the lid and tops of the partition walls of the frame.

An RF shielding structure in accordance with a second embodiment of the present invention includes an enclosure formed of a lid and a frame, wherein the frame comprises two or more compartments that are separated by partition walls, and a removable RF shielding liner having a plurality of protrusions, wherein the removable shield is configured to be sandwiched between the lid and the frame. In accordance with the present invention, when the removable RF shielding liner is in place, some or all of the protrusions provide electrical contacts between the lid and tops of the partition walls of the frame.

A third embodiment of the present invention is to provide a shielding liner that includes a substantially flat piece of conductive material, and a plurality of protrusions on at least one side of the substantially flat piece of conductive material. In the embodiment, the RF shielding liner is configured to be placed between a lid and a frame having a plurality of partition walls, whereby some or all of the plurality of protrusions provide electrical contacts between the lid and tops of the plurality of partition walls when the lid is coupled with the frame to create a Faraday Cage.

According to the present invention, the RF shielding liner is made of a conductive foil, such as copper, aluminum or any deformable substrate which may be coated or plated with a conductive material such as carbon or metal-impregnated inks. Alternatively, the RF shielding liner is made by a woven mesh of fine conductive material.

### BRIEF DESCRIPTION OF THE DRAWINGS

FIG. 1 is a perspective view of a conventional RF shielding structure.

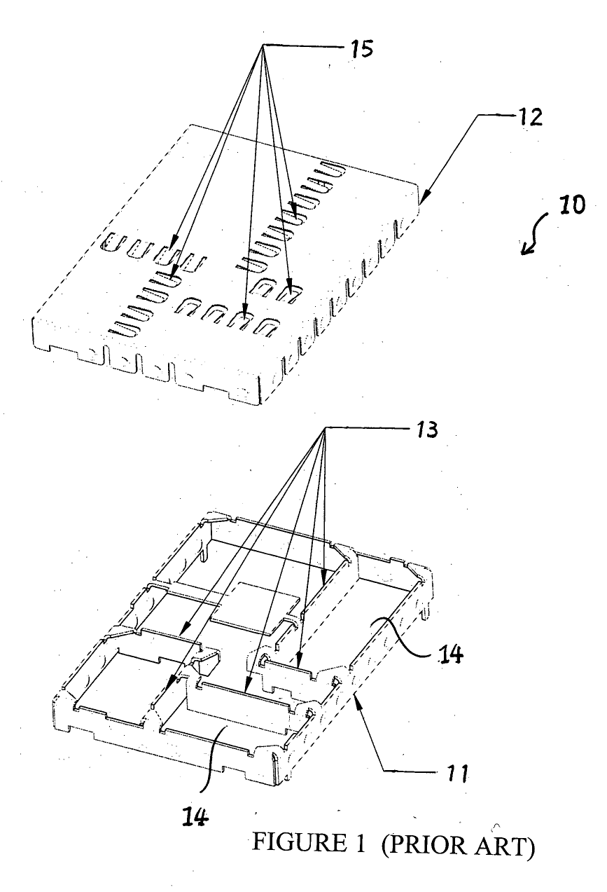

FIG. 2 is a perspective view of an RF shielding structure in accordance with the present invention.

### DETAILED DESCRIPTION OF THE INVENTION

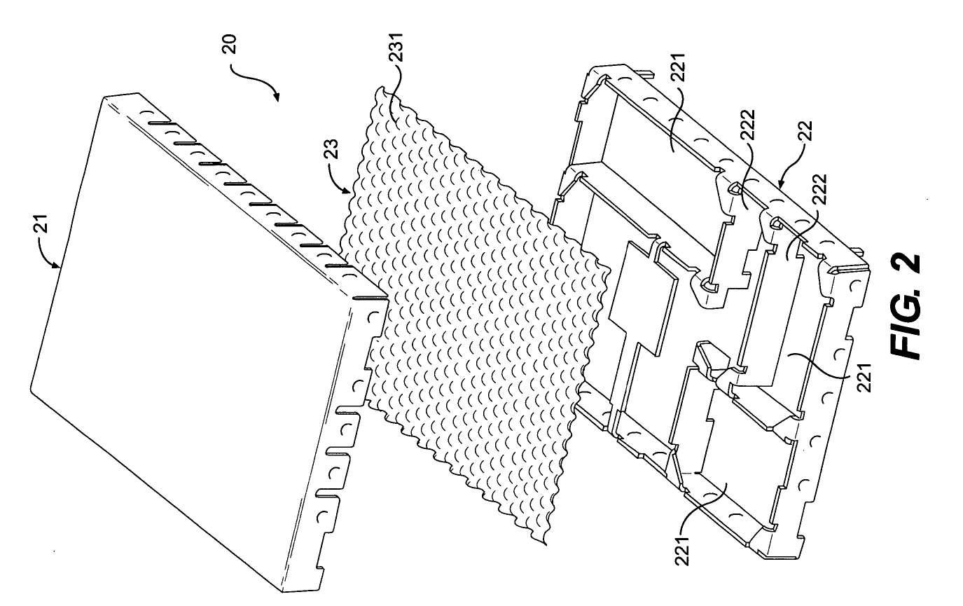

FIG. 2 is a perspective view of an RF shielding structure 20 in accordance with the present invention. As shown in the figure, RF shielding enclosure 20 includes lid 21, frame 22, and a thin conductive piece 23 made of a conductive material. Thin conductive piece 23 is also referred to as an RF shielding liner below. Preferably, conductive piece 23 is made of a metallic foil or other similar materials. Frame 22 includes two or more compartments 221, each of which is separated by respective partition walls 222. Thin conductive piece 23 can be pressured-formed to produce an array of small protrusions 231. These protrusions, also hereinafter referred to as bumps or dimples, are preferably uniformly distributed over a substantial portion of the entire surface of thin conductive piece 23. Alternatively, the protrusions may be formed over thin conductive piece 23 in a pattern that corresponds with partition walls 222. In use, thin conductive piece 23 is sandwiched between lid 21 and frame 22 so that the array of small bumps 231 are in contact with lid 21 and frame 22 to create a Faraday Cage for each compartment 221.

In accordance with the present invention, the array of small bumps 231 of conductive piece 23 can be formed on at least one side of conductive piece 23. Note that conductive piece 23 can be integrally formed with lid 21. Preferably, however, conductive piece 23 is configured to be removable. This is desirable because conductive piece 23 can be a frequently replaceable component.

Conductive piece 23 may be die-cut and installed inside of shielding lid 21. When lid 21 is closed, the bumps of conductive piece 23 are crushed against the tops of partition walls 222, thus making electrical contact with partition walls 222, at frequent intervals, thereby completing the Faraday Cage necessary for preventing the escape of unwanted radio emissions. Due to the configuration of conductive piece 23, lid 21, in accordance with the present invention, no longer requires openings in lid 21 to form contact fingers. Therefore, the manufacturing process of lid 21 is simplified.

Furthermore, the RF shielding enclosure of the present invention allows the same lid to be used for shield frames with different internal sections without the need for re-tooling the lid. The manufacturing cost is thus reduced.

In addition to metallic foils mentioned above, conductive piece 23 can also be formed of a woven mesh of fine copper or other conductive wire or any other shapes as long as the piece contacts with both of lid 21 and partition walls 222 of frame 22 to form a conductivity loop for RF. Presently, copper or aluminum foils are the cheapest and easiest materials to form and are ultra-thin, readily available, non-toxic and recyclable.

Moreover, in the case that conductive piece 23 is made of a crushable foil, the foil is intended as a one-time use piece. That is, if lid 21 is opened for any reason, the foil would likely need to be replaced.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

1. An RF shielding structure, comprising:
a frame including two or more compartments separated by partition walls;
a lid configured to mate with the frame; and
a replaceable and substantially flat RF shielding liner having a plurality of protrusions made of a conductive material, wherein when the RF shielding liner is sandwiched between the frame and the lid, some or all of the plurality of protrusions are deformed between the lid and tops of the partition walls of the frame.

2. The structure of claim 1, wherein the RF shielding liner, when some or all of the plurality of protrusions are deformed between the lid and tops of the partition walls, creates a Faraday Cage.

3. The structure of claim 1, wherein the RF shielding liner is configured to be removably installed on one side of the lid that faces the frame.

4. The structure of claim 1, wherein the plurality of protrusions are formed on one side of the RF shielding liner that faces the frame.

5. The structure of claim 1, wherein the plurality of protrusions are formed on both sides of the RF shielding liner.

6. The structure of claim 1, wherein the RF shielding liner is formed of a conductive foil.

7. The structure of claim 1, wherein the RF shielding liner is a woven mesh of fine conductive wire.

8. The structure of claim 1, wherein the RF shielding liner is made of copper.

9. The structure of claim 1, wherein the plurality of protrusions are configured to correspond with a pattern associated with the tops of the partition walls of the frame.

10. The structure of claim 1, wherein the plurality of protrusions are uniformly distributed over substantially the entire surface of the RF shielding liner.

11. An RF shielding liner, comprising:
a substantially flat piece of conductive material; and
a plurality of protrusions on at least one side of the substantially flat piece of conductive material,
wherein the RF shielding liner is configured to be placed between a lid and a frame having a plurality of partition walls and is replaceable,
whereby some or all of the plurality of protrusions provide electrical contacts between the lid and tops of the plurality of partition walls when the lid is coupled with the frame to create a Faraday Cage.

12. The liner of claim 11, wherein the plurality of protrusions are configured to correspond with a pattern associated with the tops of the partition walls of the frame.

13. The liner of claim 11, wherein the plurality of protrusions are uniformly distributed over substantially the entire surface of the RF shielding liner.

14. The liner of claim 11, wherein the plurality of protrusions are integral with the substantially flat piece of conductive material.

15. The liner of claim 11, wherein the plurality of protrusions are made of a conductive foil.

16. The liner of claim 11, wherein the substantially flat piece of conductive materials is made of copper foil.

17. The liner of claim 11, wherein the substantially flat piece of conductive material is a woven mesh of fine conductive wire.

18. An RF shielding structure, comprising:
an enclosure formed of a lid and a frame, wherein the frame comprises two or more compartments that are separated by partition walls; and
a replaceable RF shielding liner formed of a substantially flat piece having a plurality of protrusions, wherein the replaceable shielding liner is configured to be sandwiched between the lid and the frame,
wherein when the replaceable RF shielding liner is in place, some or all of the protrusions provide electrical contacts between the lid and tops of the partition walls of the frame.

19. The structure of claim 18, wherein the plurality of protrusions are configured to correspond with a pattern associated with the tops of the partition walls of the frame.

20. The structure of claim 18, wherein the plurality of protrusions are uniformly distributed over substantially the entire surface of the RF shielding liner.

21. The structure of claim 18, wherein the RF shielding liner is made of conductive materials and is in a waved shape so that when the lid and frame enclose to form the enclosure, the RF shielding liner contacts simultaneously with the lid and the tops of the partition walls of the frame.

22. The structure of claim 18, wherein the plurality of protrusions are located on at least one side of the replaceable RF shielding liner.

23. The structure of claim 18, wherein the RF shielding liner is a woven mesh of fine conductive materials.
